(19) United States
(12) Patent Application Publication
(10) Pub. No.: US 2012/0249772 A1
(43) Pub. Date: Oct. 4, 2012

(54) COMPONENT MOUNTING DEVICE, INFORMATION PROCESSING DEVICE, POSITION DETECTION METHOD, AND SUBSTRATE MANUFACTURING METHOD

(75) Inventor: Takeshi Nakamura, Saitama (JP)

(73) Assignee: Sony Corporation, Tokyo (JP)

(21) Appl. No.: 13/413,382

(22) Filed: Mar. 6, 2012

(30) Foreign Application Priority Data
Mar. 31, 2011 (JP) 2011-078448

(51) Int. Cl. H04N 7/18; H05K 3/30

(52) U.S. Cl. 348/94; 29/714; 29/832; 348/E07.085

(57) ABSTRACT

A component mounting device includes a transport unit which transports a substrate, a mounting unit which mounts a component on the substrate, a detection unit which is able to detect a first detection target which is provided on the substrate and a second detection target which is provided to be separated by a predetermined distance from the first detection target on the substrate at least in the transportation direction and is a reference position of a mounting action by the mounting unit, and a control unit which outputs a stop signal for stopping the transport of the substrate to the transport unit and detects the second detection target of the substrate which has been stopped using the detection unit based on the detection of the first detection target by the detection unit.

### CROSS REFERENCES TO RELATED APPLICATIONS

The present application claims priority to Japanese Priority Patent Application JP 2011-078448 filed in the Japan Patent Office on Mar. 31, 2011, the entire content of which is hereby incorporated by reference.

### BACKGROUND

The present application relates to a component mounting device, an information processing device, a substrate position detection method, and a substrate manufacturing method which mount a component on a substrate.

A component mounting device is typically a device in which a head takes out an electronic component by accessing a feeder which supplies the electronic component and mounts the electronic component on a circuit substrate or the like which is disposed in a region for mounting.

A technique is disclosed in Japanese Unexamined Patent Application Publication No. 2009-27202 where a substrate which is transported is stopped using a stopper in order to dispose the substrate in a region for mounting. In the technique, the substrate is stopped by the front edge portion of the substrate which is transported coming into contact with the stopper which is disposed in a predetermined position (for example, refer to paragraph and FIG. 15 in the specifications of Japanese Unexamined Patent Application Publication No. 2009-27202).

In addition, a technique is also disclosed in Japanese Unexamined Patent Application Publication No. 2009-27202 where a substrate sensor is used. In the technique, the substrate sensor detects the front edge of the substrate which is transported and outputs a stop command to a transportation device which transports the substrate. A predetermined amount of time is necessary from this point in time until the substrate actually stops. Accordingly, then, the actual stopping position of the substrate is calculated from the point in time where the front edge of the substrate is detected by the substrate sensor by calculating movement distance of the substrate due to the transportation device (for example, refer to paragraphs [0050], [0070], and the like in the specifications of Japanese Unexamined Patent Application Publication No. 2009-27202).

### SUMMARY

However, the techniques described above are not able to accurately detect the stopping position of the substrate. For example, in the case where the stopper is used, there is a problem in that the substrate bounces off the stopper and there is a rebound or the like. In addition, as described above, even with a technique where the substrate is stopped with the detection of the substrate which is transported using the substrate sensor as a trigger, the information on the actual stopping position of the substrate is only a prediction (calculation) information.

It is desirable that a component mounting device, an information processing device, a substrate position detection method, and a substrate manufacturing method are provided which accurately detect the stopping position of a substrate.

According to an embodiment of the present application, there is provided a component mounting device which includes a transport unit, a mounting unit, a detection unit, and a control unit.

The transport unit transports a substrate.

The mounting unit mounts a component on the substrate.

The detection unit is able to detect a first and a second detection target which are provided on the substrate. The second detection target is provided to be separated by a predetermined distance from the first detection target on the substrate at least in the transportation direction and is a reference position of a mounting action by the mounting unit.

The control unit outputs a stop signal for stopping the transport of the substrate to the transport unit and detects the second detection target of the substrate which has been stopped using the detection unit based on the detection of the first detection target by the detection unit.

In the embodiment, it is possible for the second detection target for starting the mounting action to be easily detected since the transportation of the substrate is stopped based on the detection of the first detection target and the second detection target on the substrate which has actually stopped is detected. That is, it is possible to accurately detect the stopping position of the substrate.

The detection unit may have a camera. In this case, the control unit outputs the stop signal so that the substrate is stopped within an imaging range of the camera and the position of the second detection target is calculated based on the position of the first detection target on the substrate which has stopped. By the first detection target on the substrate from the start of deceleration to stopping entering within the imaging range of the camera, it is possible to recognize both the output timing of the stop signal of the substrate and the position of the first detection target on the substrate which has actually stopped using the camera. Then, if the position of the first detection target on the substrate which has actually stopped is recognized, it is possible to easily detect the second detection target which is separated by a predetermined distance therefrom.

The detection unit may detect an edge portion of the substrate in the transport direction as the first detection target. Since the edge portion of the substrate becomes the first detection target, the detection is easy compared to a case where, for example, the detection unit detects a mark which is attached on the substrate.

The control unit may detect one of either out of the edge portion on the downstream side or the edge portion on the upstream side with regard to the substrate in the transport direction based on the information on the shape of the edge portions of the substrate in the transport direction. In a case where the shape of the edge portion on the downstream side or the edge portion on the upstream side with regard to the substrate is different, it is possible to select the edge portion where detection by the detection unit is easier out of the edge portions as the detection target.

The detection unit may have a detection region which is disposed further downstream than the substrate which is transported at a point in time when the control unit outputs the stop signal and the control unit may output the stop signal at a timing so that the second detection target on the substrate which is transported stops within the detection region of the detection unit. The present application uses the generation of a time lag from the output of the stop signal due to the detection of the first detection target until the stopping of the substrate which is transported. It is possible to easily detect the second detection target by the stop signal being output at a timing so that the second detection target on the substrate stops within the detection region of the detection unit.

The detection unit may detect the edge portion of the substrate on the downstream side in the transport direction as the first detection target. Since the edge portion of the substrate is the first detection target, for example, the detection is easy compared to a case where the detection unit detects a mark which is attached on the substrate.

The mounting unit may have a head which holds the component and a movement mechanism which moves the head. In this case, the detection unit may be provided so as to be able to move integrally with the head using the movement mechanism. After the position of the second detection target is calculated, the detection unit is able to move the second detection target until a position where detection is possible using the movement mechanism and start the mounting action by the head which is moved along with the detection unit with the position of the second detection target as a reference position.

The control unit may control the transport speed of the substrate using the transport unit based on information on the position of the first detection target which has been detected when the substrate has stopped. Due to this, it is possible to appropriately set the transport speed of the substrate using the transport unit to a speed which matches the detection capability of the detection unit.

The detection unit may be a camera.

According to another embodiment of the present application, there is provided an information processing device which uses a component mounting device which is provided with a transport unit, a mounting unit, and a detection unit.

The information processing device is provided with an output section and a detection control section.

The output section outputs a stop signal for stopping transport of a substrate to the transport unit based on detection of the first detection target by the detection unit.

The detection control section detects a second detection target on the substrate which has stopped using the detection unit.

According to still another embodiment of the present application, there is provided a position detection method which includes transporting of a substrate which is a component mounting target using a transport unit.

A first detection target which is provided on the substrate which is transported is detected using a detection unit.

A stop signal for stopping the transporting of the substrate is output to the transport unit based on detection of the first detection target using the detection unit.

A second detection target, which is provided on the substrate which has stopped and is provided to be separated by a predetermined distance from the first detection target on the substrate at least in the transportation direction, is detected using a detection unit. The second detection target is a reference position in a component mounting action.

According to still another embodiment of the present application, there is provided a substrate manufacturing method which includes transporting of a substrate which is a component mounting target by a transport unit.

A first detection target which is provided on the substrate which is transported is detected by a detection unit.

A stop signal for stopping the transporting of the substrate is output to the transport unit based on detection of the first detection target by the detection unit.

A second detection target, which is provided on the substrate which has stopped and is provided to be separated by a predetermined distance from the first detection target on the substrate at least in the transportation direction, is detected by a detection unit.

The component is mounted on the substrate with the second detection target which has been detected as a reference position.

Above, according to the embodiments of the present application, it is possible to accurately detect the stop position of the substrate.

Additional features and advantages are described herein, and will be apparent from the following Detailed Description and the figures.

### BRIEF DESCRIPTION OF THE FIGURES

FIG. 1 is a front surface diagram illustrating in a schematic manner a component mounting device according to a first embodiment of the present application;

FIG. 2 is a planar diagram of the component mounting device which is shown in FIG. 1;

FIG. 3 is a side surface diagram of the component mounting device which is shown in FIG. 1;

FIG. 4 is a block diagram illustrating a configuration of a control system of a component mounting device;

FIG. 5 is a flowchart illustrating mainly a process of a main controller when a position of a substrate is detected;

FIGS. 6A to 6D are schematic diagrams for illustrating a detection action of a position of a substrate;

FIGS. 7A to 7D are schematic diagrams for illustrating a detection action of a substrate position according to a second embodiment of the present application; and

FIGS. 8A to 8C are schematic diagrams for illustrating a detection action of a substrate position according to the second embodiment of the present application.

### DETAILED DESCRIPTION

The present application will be described below in greater detail with reference to the drawings according to an embodiment.

As described above, there are problems such as components with large heights which are mounted on a substrate being bent or removed due to the force of collision in a case where the transport of the substrate is stopped using a stopper.

In addition, for example, in a case where a mounting action is started by a substrate camera 17 recognizing an alignment mark D on the substrate, if the substrate bounces off the stopper and rebounds, the substrate camera 17 is not able to accurately recognize the alignment mark D due to the amount of the bounce back.

Furthermore, in the case of the stopper, a raising and lowering action of the stopper is necessary and excess time is taken in the positioning of the substrate to the extent of the raising and lowering action.

The present application which is described below is able to resolve the problems above. Below, embodiments of the present application will be described while referencing the diagrams.

### [Configuration of Component Mounting Device]

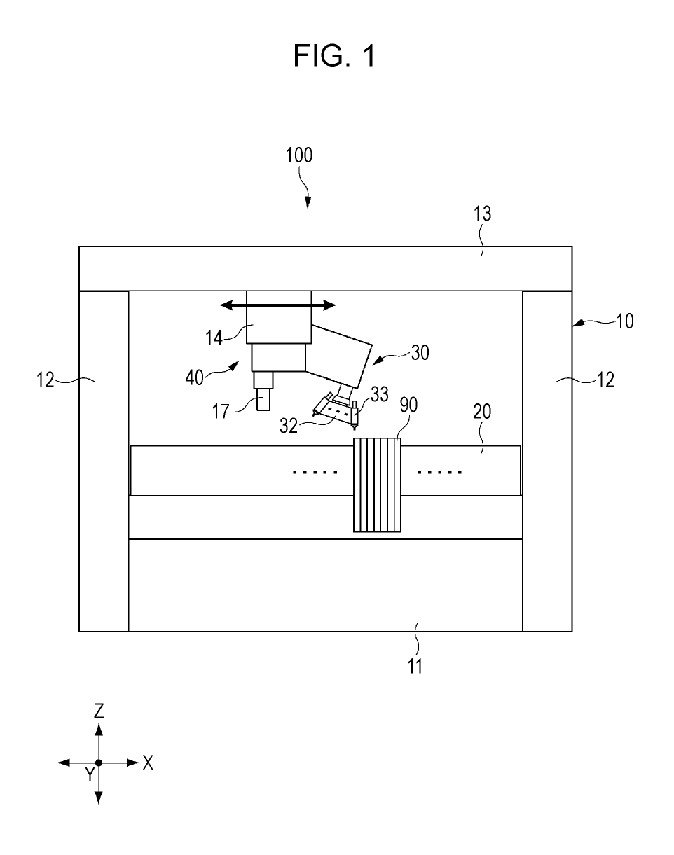

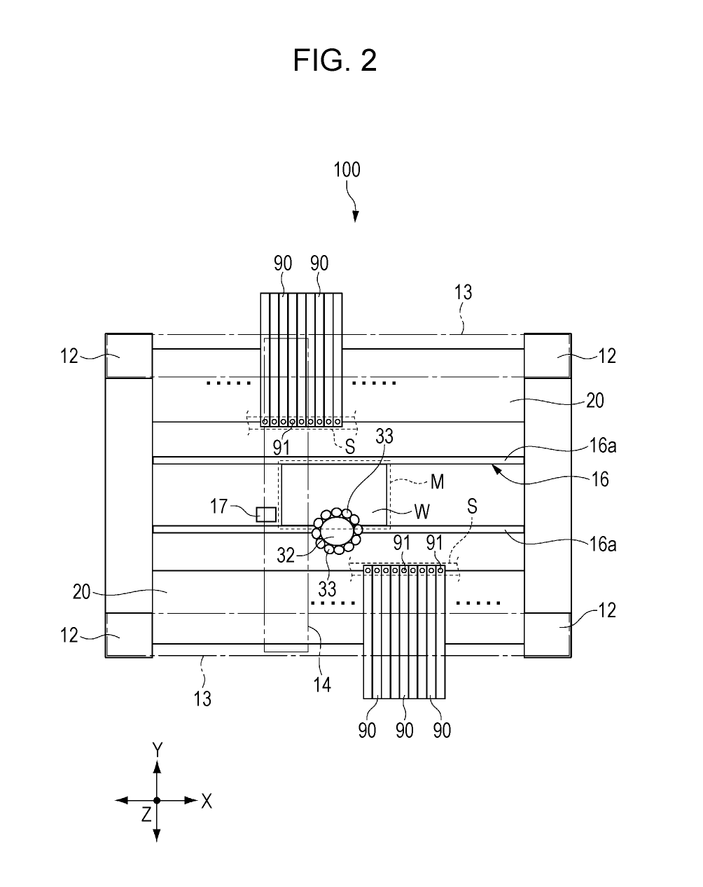

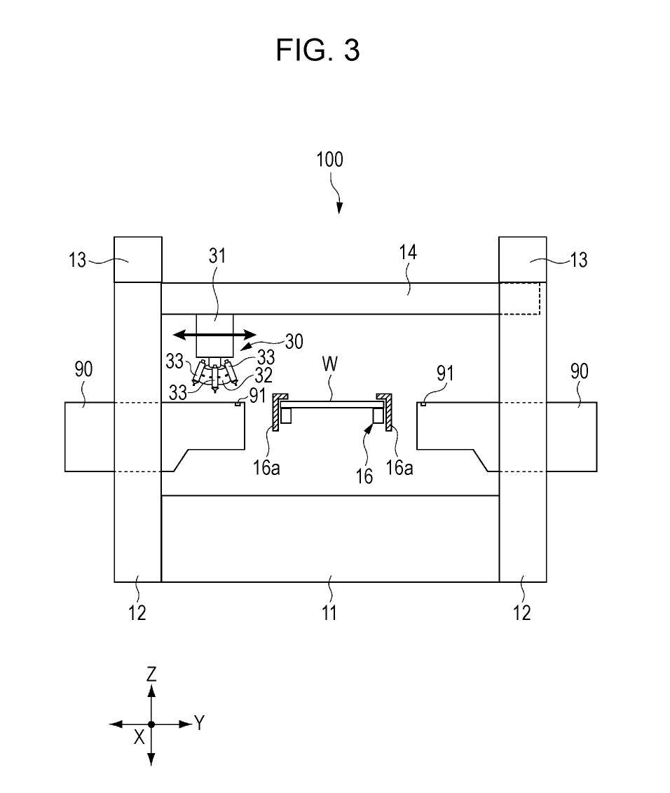

FIG. 1 is a front surface diagram illustrating in a schematic manner a component mounting device according to a first embodiment of the present application. FIG. 2 is a planar diagram of a component mounting device 100 which is shown in FIG. 1, and FIG. 3 is a side surface diagram thereof

The component mounting device 100 is provided with a frame 10, a mounting head 30 which holds a component which is not shown and mounted the component on a circuit substrate (referred to below simply as a substrate) W which is a mounting target, a tape feeder installation section 20 where a tape feeder 90 is installed, and a transport unit 16 (refer to FIG. 2) which holds and transports the substrate W.

The frame 10 has a base 11 which is provided on a bottom portion and a plurality of supporting pillars 12 which are fixed to the base 11. In the upper portion of the plurality of supporting pillars 12, for example, two X beams 13 which span along the X axis in the diagram are provided. For example, between the two X beams 13, a Y beam 14 spans along the Y axis and the mounting head 30 is connected to the Y beam 14. In the X beams 13 and the Y beam 14, an X axis movement mechanism and a Y axis movement mechanism which are not shown are provided, and as such, it is possible for the mounting head 30 to move along the X axis and the Y axis. The X axis movement mechanism and the Y axis movement mechanism are typically configured using a ball screw driving structure, but other structures such as a belt driving structure may be used.

A mounting unit 40 is configured from the mounting head 30, the X axis movement mechanism, and the Y axis movement mechanism. There are cases where a plurality of the mounting units 40 are provided mainly in order to improve efficiency, and in this case, the plurality of mounting heads 30 are driven in the X and Y axial directions independently.

As shown in FIG. 2, the tape feeder installation section 20 is disposed on both the front portion side (lower side in FIG. 2) and the rear portion side (upper side in FIG. 2) of the component mounting device 100. The Y axial direction in the diagram is the front and back direction of the component mounting device 100. In the tape feeder installation section 20, a plurality of the tape feeders 90 are installed so as to line up along the X axial direction. For example, it is possible for 40 to 70 of the tape feeders 90 to be installed on the tape feeder installation section 20. In the embodiment, it is possible for 58 of the tape feeders 90 on each of the front portion and the rear portion, a total of 116, to be installed.

Here, the tape feeder installation section 20 is configured to be provided on both the front edge side and the rear edge side of the component mounting device 100, but the tape feeder installation section 20 may be configured to be provided on either one the front edge side or the rear edge side.

The taper feeder 90 is formed to be long in the Y axial direction. The details of the tape feeder 90 are not shown in the diagram, but a reel is provided and carrier tape which contains an electronic component such as a condenser, a resistor, an LED, or an IC packaging is wound on the reel. In addition, the tape feeder 90 is provided with a structure for feeding out the carrier tape by step feeding and the electronic components are supplied one at a time for each of the step feeds. As shown in FIG. 2, a supply window 91 is formed in the upper surface of the edge portion of a cassette of the tape feeder 90 and the electronic component is supplied via the supply window 91. A region where a plurality of the supply windows 91 are lined up, which is formed along the X axial direction due to the plurality of tape feeders 90 being lined up, is an electronic component supply region S.

Here, in the carrier tape of one of the tape feeders 90, a plurality of the same electronic component is contained. There are cases where the same electronic component is contained over a plurality of the tape feeders 90 out of the tape feeders 90 which are mounted on the tape feeder installation section 20.

The transport unit 16 described above is provided in the central portion of the component mounting device 100 in the Y axial direction and the transport unit 16 transports the substrate W along the X axial direction. For example, as shown in FIG. 2, a region on the substrate W, which is supported by the transport unit 16 in substantially the central portion on the transport unit 16 in the X axial direction, is a mounting region M where the mounting of the electronic component is performed due to accessing by the mounting head 30.

As will be described later, the component mounting device 100 detects an accurate position on the substrate W, which is transported up to the mounting region M, using the substrate camera 17. After the accurate position of the substrate W has been detected, the mounting unit 40 starts the electronic component mounting action.

The mounting head 30 is provided with a carriage 31 which is connected to the Y axis movement mechanism of the Y beam 14, a turret 32 which is provided so as to extend diagonally downward from the carriage 31, and a plurality of suction nozzles 33 which is attached along the circumference direction of the turret 32. The suction nozzles 33 take out and hold the electronic component from the carrier tape due to a vacuum suction action. The suction nozzles 33 are able to move up and down so as to mount the electronic component on the substrate W. For example, 12 of the suction nozzles 33 are provided.

The mounting head 30 is able to move in the X and Y axial directions as described above, the suction nozzles 33 move between the supply region S and the mounting region M, and in addition, moves in the X and Y axial directions in the mounting region M so as to execute the mounting in the mounting region M.

The turret 32 is able to rotate (spin) with a shaft in a diagonal direction as the central rotation shaft. The suction nozzles 33 which are disposed so that the length direction of the suction nozzles 33 is along the Z direction out of the plurality of suction nozzles 33 are the suction nozzles 33 which are selected for mounting the electronic component on the substrate W. An arbitrary one of the suction nozzles 33 is selected using the rotation of the turret 32. The electronic component is suctioned and held by the suction nozzles 33 which have been selected accessing the supply window 91 of the tape feeder 90 and the electronic components are mounted on the substrate W by being moved and lowered to the mounting region M.

The mounting head 30 holds each of a plurality of the electronic components continuously in one process with the plurality of suction nozzles 33 while the turret 32 rotates. In addition, the electronic components which are suctioned by the plurality of suction nozzles 33 are mounted on one substrate W continuously in one process.

As shown in FIG. 1, the substrate camera 17 which detects the position of the substrate W is attached in the mounting head 30. The substrate camera 17 is able to move integrally with the mounting head 30 using the X axis and Y axis movement mechanisms. The substrate camera 17 is disposed on an upper portion of the transport unit 16 and images an image of the substrate W from the upper portion side when the position of the substrate W is detected. As will be described later, the substrate camera 17 recognizes an alignment mark which is provided on the substrate W and the mounting unit 40 mounts the electronic component on the substrate W with the alignment mark as the reference position.

The substrate camera 17 has a CCD (Charged Coupled Device), a CMOS (Complementary Metal-Oxide Semiconductor), or the like. The substrate camera 17 may recognize light which has a wavelength region which is mainly visible light or may recognize light which has a wavelength range which is mainly infrared light.

The transport unit 16 is typically a belt type of conveyer, but is not limited thereto and may be any of a roller type, a type where a support mechanism which supports the substrate W moves by sliding, a non-contact type, or the like. The transport unit has a guide rail 16a which is provided along the X axial direction. Due to this, there is transportation with deviation in the Y axial direction of the substrate W which is transported being regulated.

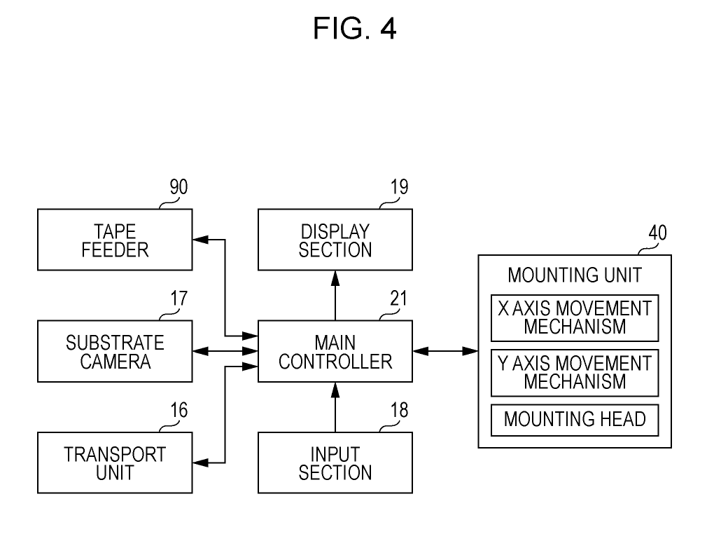

FIG. 4 is a block diagram illustrating a configuration of a control system of the component mounting device 100.

The control system has a main controller 21 (or a host computer). In the main controller 21, the tape feeder 90, the substrate camera 17, the transport unit 16, the mounting unit 40, an input section 18, and a display section 19 are electrically connected.

The tape feeder 90 has a built-in memory which is not shown. The built-in memory is electrically connected to the main controller 21 by the tape feeder 90 being set in the tape feeder installation section 20. In the built-in memory, information on the electronic component which is contained in the tape feeder 90 is stored in advance. Due to this, the main controller 21 recognizes which of the tape feeders 90 which has which type of electronic component is set in which position in the tape feeder installation section 20. The information on the electronic component is information such as the type of the electronic component or the number of the electronic components which the tape feeder 90 has.

Alternatively, the information on which of the tape feeders 90 which has which type of the electronic component is set in which position in the tape feeder installation section 20 may be input into the main controller 21 via the input section 18 manually by an operator.

In each of the movement mechanisms and the mounting head 30 of the mounting unit 40, motors (not shown) which are installed therein and drivers which drive each of the motors are provided. The drivers drive each of the movement mechanisms and the mounting head 30 according to control signals due to the main controller 21 outputting the control signals to the drivers.

The input section 18 is a device which, for example, is operated by the operator for the operator to input information which is necessary for the mounting process such as the type of the substrate W which is the mounting target to the main controller 21. The display section 19 is a device which, for example, displays information which is input via the input section 18 by the operator, information which other information which is necessary.

The main controller 21 has, for example, a function of a computer such as a CPU, a RAM, and a ROM and functions as a control unit. The main controller 21 may be realized by a device such as a PLD (Programmable Logic Device) such as a FPGA (Field Programmable Gate Array) or another ASIC (Application Specific Integrated Circuit).

### Substrate Position Detection Method of First Embodiment

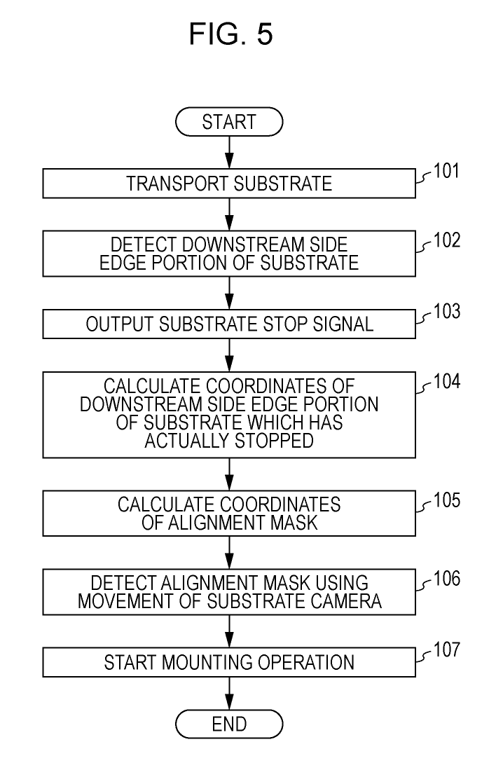

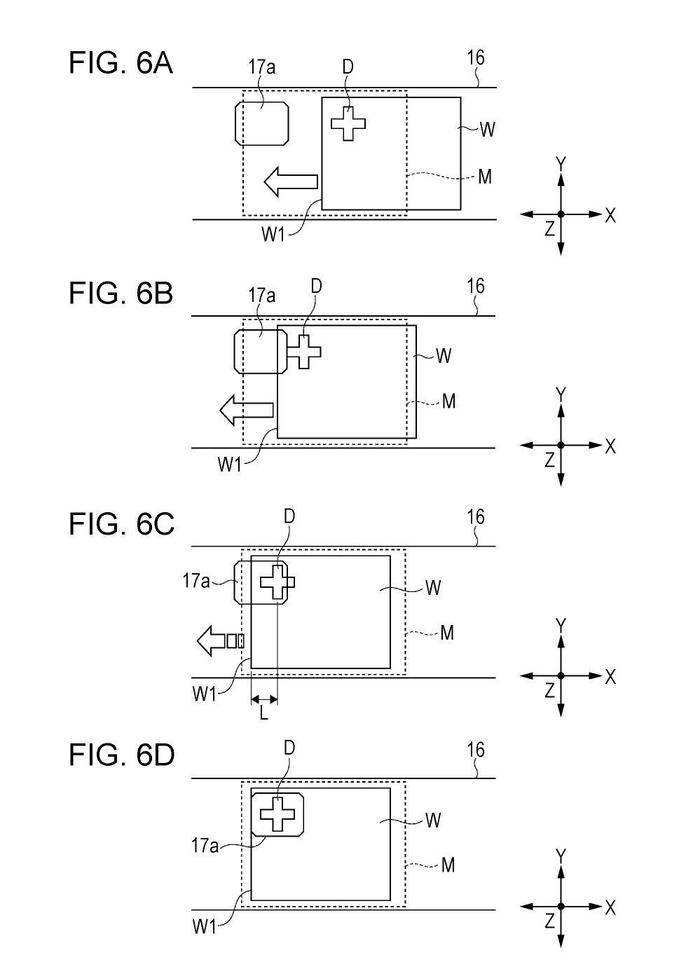

FIG. 5 is a flowchart illustrating mainly a process of the main controller 21 when the position of the substrate W is detected. FIGS. 6A to 6D are schematic diagrams for describing a detection action of the position of the substrate W.

Before the component mounting device 100 starts the mounting process, the operator inputs information which is necessary for the mounting process, for example, information on the type of substrate and the like, to the main controller 21 via the input section 18.

As one example, the substrate camera 17 waits at the downstream side of the substrate W in the transport direction (the direction from the right side to the left side in FIGS. 6A to 6D) and is stationary at a position so that an imaging range 17a (the detection region) overlaps with the mounting position M. In addition, the substrate camera 17 matches in practice a position in a direction which intersects with the transport direction (the Y axial direction) with a position in the Y axial direction which is the alignment mark D which is a second detection target provided on the substrate W which is the mounting target. Typically, the Y coordinate of the central position of the imaging range 17a is matched in practice with the Y coordinate of the alignment mark D. The alignment mark D is provided in the downstream edge portion W1 which is a first detection target so as to be separated by a predetermined distance from the downstream edge portion W1 at least in the transportation direction.

The main controller 21 has the information on the type of substrate as described above. Accordingly, it is sufficient if the substrate camera 17 stores the position (here, the position of the Y coordinate) of the alignment mark D which the substrate W which is the mounting target has and waits at the position in the Y axial direction according to the position of the alignment mark.

Here, the transport unit 16 is set so that deviation in the position of the substrate W in the Y direction is not generated in practice using the guide rail 16a as described above. Accordingly, it is sufficient if the substrate camera 17 waits at the position of the Y coordinate which has been determined in advance (according to the position of the alignment mark D).

As shown in FIG. 6A, the substrate W is transported into the component mounting device 100 (step 101). Then, as shown in FIG. 6B, the substrate camera 17 detects the downstream edge portion W1 which is the first detection target of the substrate W (step 102). Here, the substrate W is recognized using an existing image processing technique. For example, it is possible to recognize the substrate W using the difference in the brightness of the substrate W and the brightness of the background at the downstream side in the Z axial direction due to the substrate W.

When the downstream edge section W1 of the substrate W is detected by the substrate camera 17, the main controller 21 outputs the stop signal for stopping the transporting of the substrate W to the transport unit 16 (step 103). At this time, the main controller 21 at least has the function as an output section of an information processing device.

The transport unit 16 receives the stop signal and actually stops the substrate W by stopping the transporting thereof As shown in FIG. 6B, since there is a time lag from the detection of the downstream edge portion W1 of the substrate W by the substrate camera 17 until the substrate W actually is stopped, the substrate W moves a predetermined distance in the time lag as shown I FIG. 6C. Alternatively, even if the time lag is sufficiently short, there may be a slip due to the inertia of the substrate W on the transport belt. Below, the distance which the substrate W moves in the time lag and the like is referred to as a surplus movement distance L.

The surplus movement distance L is set so as to be within the imaging range 17a of the substrate camera 17 in advance. The size of the imaging range 17a is, for example, 4 mm×4 mm, but is not limited thereto.

The main controller 21 calculates the coordinate (here, X coordinate) of the downstream edge portion W1 based on the image information of the downstream edge portion W1 of the substrate W when the substrate W has actually stopped which is acquired via the substrate camera 17 (step 104).

The main controller 21 calculates the position of the alignment mark D based on the coordinates of the downstream edge portion W1 (step 105). The alignment mark D is provided in a predetermined position on the substrate according to, for example, the type of substrate. Since the main controller 21 acquires the information on the type of substrate at the start, there is information on the coordinates of the alignment mark D in the substrate W which is included in the information on the type of substrate. Accordingly, the main controller 21 is able to calculate the coordinates of the alignment mark D which is a position which is separated from the downstream edge portion W1 by the predetermined distance.

When the main controller 21 calculates the alignment mark D, the substrate camera 17 is moved so that the alignment mark D enters the imaging range 17a as shown in FIG. 6D. Typically, the substrate camera 17 is moved so that the central position of the alignment mark D matches with the central position of the imaging range 17a. Due to this, the substrate camera 17 recognizes the alignment mark D (step 106). Then, in step 107, the main controller 21 starts the mounting action using the mounting head 30 with the coordinates of the alignment mark D as the reference.

Here, in FIG. 6C, a portion of the alignment mark D enters the imaging range 17a when the substrate W moves the surplus movement distance L and is stopped. This is because the size of the imaging range 17a and the alignment mark D are schematically shown to be large with regard to the size of the substrate W. Accordingly, naturally, there are cases where the alignment mark D does not enter the imaging range 17a when the substrate W is stopped.

The shape of the alignment mark is a cross shape in FIGS. 6A to 6D, but may be any of a circle, a square, a star shape, or the like.

As described above, in the embodiment, the alignment mark D of the substrate W, where the stop signal is output, and after that, the transporting of the substrate W has been actually stopped when the downstream edge portion W1 of the substrate W has been detected (based on the detection), is detected. Accordingly, it is possible to easily detect the alignment mark D for the mounting head 30 to start the mounting action. That is, it is possible for the stop position of the substrate W to be accurately detected and it is possible for the substrate camera 17 to be moved to an appropriate position where the alignment mark D enters the imaging range 17a.

Being based on the detection of the downstream edge portion W1 of the substrate W is not limited to the “instant” that the downstream edge portion W1 is detected. The meaning of “based” includes the concept where there is a time lag until the stop signal is output with the detection of the downstream edge portion W1 as a trigger.

In the embodiment, the substrate camera 17 is used in the detection of the downstream edge portion W1. In particular, by the downstream edge portion W1 of the substrate W from the start of deceleration to stopping entering the imaging range 17a of the substrate camera 17, both the timing of the output of the stop signal of the substrate W and the position of the downstream edge portion W1 which has been actually stopped are able to be recognized using the substrate camera 17. It is possible for the alignment mark D which is separated from the downstream edge portion W1 to be easily detected if the position of the downstream edge portion W1 of the substrate W which is actually stopped is recognized.

In the embodiment, since the downstream edge portion W1 of the substrate W is detected, the detection is easy compared to the case where, for example, a mark or the like which is attached to the substrate W is detected.

### Substrate Position Detection Method of Second Embodiment

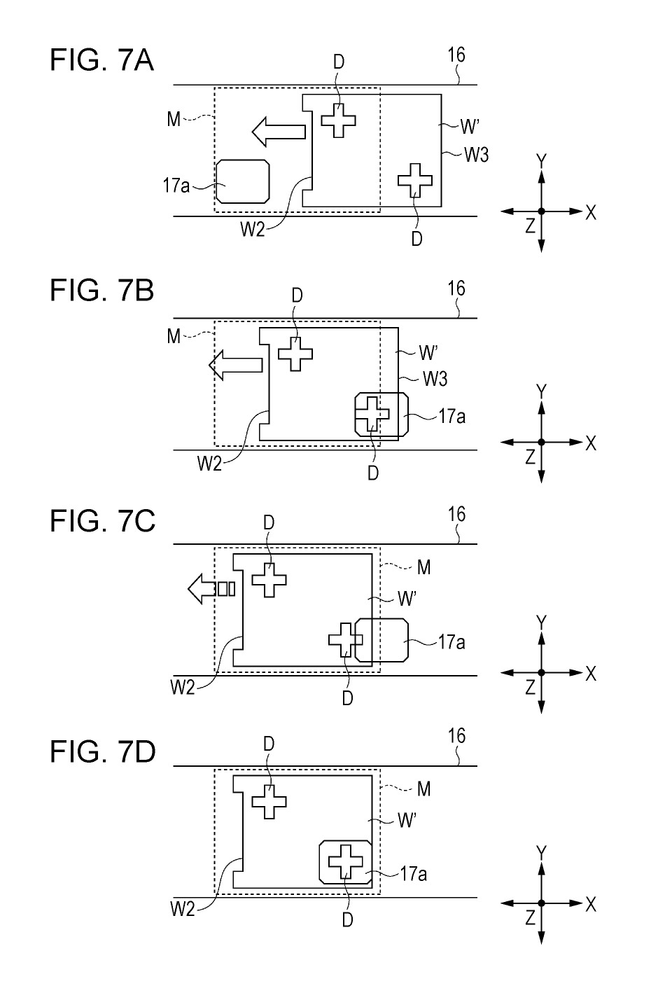

FIGS. 7A to 7D are schematic diagrams for describing the detection action of the substrate position according to a second embodiment of the present application. In the description from here, the description of the members and functions which are included in the component mounting device 100 according to the embodiment above and the similarities with regard to the actions and the like which are shown in FIGS. 5 to 6D is simplified or omitted and the points which differ are the focus of the description.

The shape of a downstream edge portion W2 of a substrate W′ according to the embodiment is different to the shape of the edge portion of the normal substrate W (refer to FIG. 6) and is a concave shape (notch shape) and an upstream edge portion W3 is a linear shape in the same manner as the normal substrate. That is, the substrate W′ is a so-called abnormal substrate.

In a case where the substrate W′ is transported, as shown in FIG. 7A, the substrate camera 17 waits by being positioned in front (at a lower side in FIG. 7A) in the Y axial direction on the transport unit 16. In the substrate W′, the alignment mark D which is provided in the vicinity of the downstream edge portion W2 and the alignment mark D which is provided in the vicinity of the upstream edge portion W3 are coordinates which are different in the Y axial direction. In the example, the substrate camera 17 detects the alignment mark D which is provided in the vicinity of the upstream edge portion W3. Here, there are cases where the normal substrate W shown in FIGS. 6A to 6D also has two alignment marks D as in the substrate W′.

As shown in FIG. 7B, the downstream edge portion W2 of the substrate W′ passes too far past the imaging range 17a of the substrate camera 17. When the upstream edge portion W3 of the substrate W′ enters the imaging range 17a, the main controller 21 outputs the stop signal to the transport unit 16.

As shown in FIG. 7C, the substrate W′ moves the surplus movement distance and is stopped. The main controller 21 recognizes the coordinates (here, the X coordinates) of the upstream edge portion W3 of the substrate W′ which has been stopped.

The main controller 21 calculates the coordinates of the upstream edge portion W3 and the position of the alignment mark D on the upstream based on the information on the substrate and moves the substrate camera 17 to the coordinates of the alignment mark D as shown in FIG. 7D. Then, the mounting head 30 starts the mounting action with the position of the alignment mark D as the reference.

In the embodiment such as this, it is possible for the main controller 21 to select the upstream edge portion W3, which is where the detection using the substrate camera 17 is easier out of the edge portions, as the detection target in a case where the shape of the downstream edge portion W2 of the substrate is different from normal.

In the embodiment, the substrate which has a shape where the shape of the downstream edge portion W1 is a shape which is different from normal is used as the substrate which is the mounting target. However, a substrate where the shape of the upstream edge portion is a shape which is different from normal may be used as the substrate which is the mounting target. In this case, the main controller 21 detects the downstream edge portion W1 and detects the alignment mark D based on the detection as in the first embodiment described above.

As the abnormal substrate, other than the substrate where the edge portion is concave, there are cases where there is a substrate where the edge portion is convex, diagonal, curved or a shape which is a combination of these.

### Substrate Position Detection Method of Third Embodiment

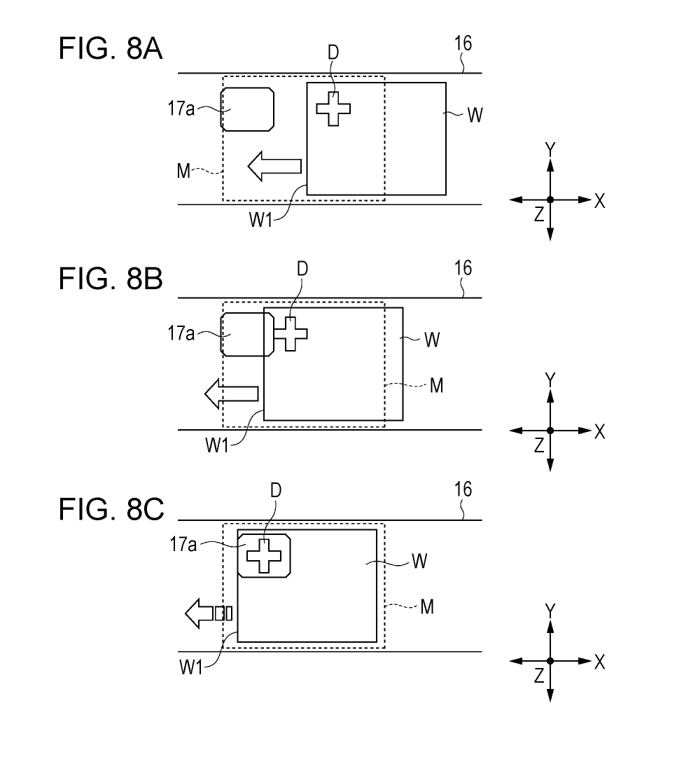

FIGS. 8A to 8C are schematic diagrams for describing the detection action of the substrate position according to the second embodiment of the present application.

As shown in FIG. 8A, the substrate W is transported. The imaging range 17a which is the detection region of the substrate camera 17 is disposed further to the downstream side than the substrate W.

As shown in FIG. 8B, the main controller 21 outputs the stop signal based on the detection of the downstream edge portion W1 of the substrate W in the imaging range 17a. At this time, the main controller 21 outputs the stop signal at a timing where the alignment mark D on the substrate W which is transported is stopped in the imaging range 17a. By the main controller 21 storing the information which is related to the information on the substrate W and the surplus distance information L described above, it is possible for the action such as this to be realized. Due to this, as shown in FIG. 8C, the output timing of the stop signal is slightly delayed and the alignment mark D enters the imaging range 17a at a timing when the substrate W is actually stopped.

In this manner, the embodiment uses the generation of the time lag from the output of the stop signal due to the detection of the downstream edge portion W1 until the substrate W which is transported is actually stopped. It is possible to easily detect the alignment mark D by outputting the stop signal at a timing when the alignment mark D of the substrate W is stopped in the imaging range 17a of the substrate camera 17.

### Other Embodiments

The present application is not limited to the embodiments described above and other various embodiments are able to be realized.

In the embodiment described above, there is an example where the substrate camera 17 is the detection unit. However, a sensor other than a camera, for example, a line sensor, may be used as the unit which detects the first detection target (for example, the substrate edge portion). It is possible to use, for example, a light sensor as the line sensor. A first sensor which is a line sensor detects the downstream edge portion W1 of the substrate W, the main controller 21 outputs the stop signal, and furthermore, a second sensor detects the downstream edge portion W1 of the substrate W which has actually stopped. Then, the main controller 21 calculates the position of the alignment mark D based on the position of the downstream edge portion W1 and the second sensor described above or another third sensor detects the alignment mark D. The second sensor described above may be a line sensor or may be a camera sensor. A camera is used as the third sensor.

By using a portion out of a plurality of lines along the X axial direction for each pixel in the substrate camera 17, the substrate camera 17 may be used as a sensor which is close to the line sensor.

The substrate camera 17 may not be provided so as to be integral with the mounting head 30. That is, there may be a form where the movement of the substrate camera 17 and the mounting head 30 are individually independent. This is the same as the case where a line sensor or another sensor is used instead of the substrate camera 17.

The main controller 21 may control the transport speed of the substrate using the transport unit 16 based on the coordinates of the edge portion of the substrate which has been detected when the substrate stops. For example, in a case where the edge portion of the substrate which has actually stopped is excluded from the imaging range 17a or is in a state which is close to being excluded, the main controller 21 is able to set the transport speed of the substrate which is the next mounting target to be lower to the extent of a predetermined speed. Due to this, it is possible for the transport speed of the substrate due to the transport unit 16 to be an appropriate speed which matches the detection capability of the substrate camera 17.

In the description above, the main controller 21 before the mounting process stores various pieces of information on the substrate which is the mounting target. However, for example, when a second substrate, which is the next mounting target of a first substrate which is the mounting target, is waiting at the upstream side of the mounting region M, the type of the substrate (shape and the like) of the second substrate may be identified using a sensor such as a camera.

In the embodiment described above, the substrate camera 17 detects the edge portion of the substrate as the first detection target for outputting the stop signal of the substrate. However, the first detection target may not be the edge portion and may be a mark which is provided at a position which is different to the alignment mark D in the transport direction and which is able to be recognized by the substrate camera 17 (or another sensor described above). The mark is, for example, a perforation, a guide line, or another mark which is able to be identified.

The mounting head 30 is provided with the turret 32 which rotates and the plurality of suction nozzles 33. However, the mounting head may have only one suction nozzle. Alternatively, the mounting head may not have the turret which rotates and may be a linear type where a plurality of suction nozzles which are lined up in a linear manner.

Out of the characteristic sections of each of the embodiments which are described above, it is possible for at least two of the characteristic sections to be combined.

It is possible for the present application to be configured as below.
(1) A component mounting device which is provided with a transport unit which transports a substrate, a mounting unit which mounts a component on the substrate, a detection unit which is able to detect a first detection target which is provided on the substrate and a second detection target which is provided to be separated by a predetermined distance from the first detection target on the substrate at least in the transportation direction and is a reference position of a mounting action by the mounting unit, and a control unit which outputs a stop signal for stopping the transport of the substrate to the transport unit and detects the second detection target of the substrate which has been stopped using the detection unit based on the detection of the first detection target by the detection unit.
(2) The component mounting device described in (1) where the detection unit has a camera, and the control unit outputs the stop signal so that the substrate is stopped within an imaging range of the camera and the position of the second detection target is calculated based on the position of the first detection target on the substrate which has stopped.
(3) The component mounting device described in (1) or (2) where the detection unit detects an edge portion of the substrate in the transport direction as the first detection target.
(4) The component mounting device described in one out of any of (1) to (3) where the control unit detects one of either out of the edge portion on the downstream side or the edge portion on the upstream side with regard to the substrate in the transport direction based on the information on the shape of the edge portions of the substrate in the transport direction.
(5) The component mounting device described in (1) where the detection unit has a detection region which is disposed further downstream than the substrate which is transported at a point in time when the control unit outputs the stop signal, and the control unit outputs the stop signal at a timing so that the second detection target on the substrate which is transported stops within the detection region of the detection unit.
(6) The component mounting device described in (5) where the detection unit detects the edge portion of the substrate on the downstream side in the transport direction as the first detection target.
(7) The component mounting device described in one out of any of (1) to (6) where the mounting unit has a head which holds the component and a movement mechanism which moves the head, and the detection unit is provided so as to be able to move integrally with the head using the movement mechanism.
(8) The component mounting device described in one out of any of (1) to (7) where the control unit controls the transport speed of the substrate using the transport unit based on information on the position of the first detection target which has been detected when the substrate has stopped.
(9) The component mounting device described in (1) or (5) where the detection unit is a camera.
(10) An information processing device which uses a component mounting device, which is provided with a transport unit which transports a substrate, a mounting unit which mounts a component on the substrate, and a detection unit which is able to detect a first detection target which is provided on the substrate and a second detection target which is provided to be separated by a predetermined distance from the first detection target on the substrate at least in the transportation direction and is a reference position of a mounting action by the mounting unit, which is provided with an output section which outputs a stop signal for stopping transport of a substrate to the transport unit based on detection of the first detection target by the detection unit, and a detection control section which detects a second detection target on the substrate which has stopped using the detection unit.
(11) A position detection method which includes transporting of a substrate which is a component mounting target using a transport unit, detecting a first detection target which is provided on the substrate which is transported using a detection unit, outputting a stop signal for stopping the transporting of the substrate to the transport unit based on detection of the first detection target using the detection unit, and detecting a second detection target, which is provided on the substrate which has stopped, is provided to be separated by a predetermined distance from the first detection target on the substrate at least in the transportation direction, and is a reference position in a component mounting action, using a detection unit.
(12) A substrate manufacturing method which includes transporting of a substrate which is a component mounting target using a transport unit, detecting a first detection target which is provided on the substrate which is transported using a detection unit, outputting a stop signal for stopping the transporting of the substrate to the transport unit based on detection of the first detection target using the detection unit, detecting second detection target, which is provided on the substrate which has stopped and is provided to be separated by a predetermined distance from the first detection target on the substrate at least in the transportation direction, using a detection unit, and mounting the component on the substrate with the second detection target which has been detected as a reference position.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A component mounting device comprising:
a transport unit which transports a substrate;
a mounting unit which mounts a component on the substrate;
a detection unit which is able to detect a first detection target which is provided on the substrate and a second detection target which is provided to be separated by a predetermined distance from the first detection target on the substrate at least in the transportation direction and is a reference position of a mounting action by the mounting unit; and
a control unit which outputs a stop signal for stopping the transport of the substrate to the transport unit and detects the second detection target of the substrate which has been stopped using the detection unit based on the detection of the first detection target by the detection unit.

2. The component mounting device according to claim 1,
wherein the detection unit has a camera, and
the control unit outputs the stop signal so that the substrate is stopped within an imaging range of the camera and the position of the second detection target is calculated based on the position of the first detection target on the substrate which has stopped.

3. The component mounting device according to claim 1,
wherein the detection unit detects an edge portion of the substrate in the transport direction as the first detection target.

4. The component mounting device according to claim 1,
wherein the control unit detects one of either out of the edge portion on the downstream side or the edge portion on the upstream side with regard to the substrate in the transport direction based on the information on the shape of the edge portions of the substrate in the transport direction.

5. The component mounting device according to claim 1,
wherein the detection unit has a detection region which is disposed further downstream than the substrate which is transported at a point in time when the control unit outputs the stop signal, and
the control unit outputs the stop signal at a timing so that the second detection target on the substrate which is transported stops within the detection region of the detection unit.

6. The component mounting device according to claim 5,
wherein the detection unit detects the edge portion of the substrate on the downstream side in the transport direction as the first detection target.

7. The component mounting device according to claim 1,
wherein the mounting unit has a head which holds the component and a movement mechanism which moves the head, and
the detection unit is provided so as to be able to move integrally with the head using the movement mechanism.

8. The component mounting device according to claim 1,
wherein the control unit controls the transport speed of the substrate using the transport unit based on information on the position of the first detection target which has been detected when the substrate has stopped.

9. The component mounting device according to claim 1,
wherein the detection unit is a camera.

10. An information processing device which uses a component mounting device, which is provided with a transport unit which transports a substrate, a mounting unit which mounts a component on the substrate, and a detection unit which is able to detect a first detection target which is provided on the substrate and a second detection target which is provided to be separated by a predetermined distance from the first detection target on the substrate at least in the transportation direction and is a reference position of a mounting action by the mounting unit, comprising:
an output section which outputs a stop signal for stopping transport of a substrate to the transport unit based on detection of the first detection target by the detection unit; and
a detection control section which detects a second detection target on the substrate which has stopped using the detection unit.

11. A position detection method comprising:
transporting of a substrate which is a component mounting target using a transport unit;
detecting a first detection target which is provided on the substrate which is transported using a detection unit;
outputting a stop signal for stopping the transporting of the substrate to the transport unit based on detection of the first detection target using the detection unit; and
detecting a second detection target, which is provided on the substrate which has stopped, is provided to be separated by a predetermined distance from the first detection target on the substrate at least in the transportation direction, and is a reference position in a component mounting action, using a detection unit.

12. A substrate manufacturing method comprising:
transporting of a substrate which is a component mounting target using a transport unit;
detecting a first detection target which is provided on the substrate which is transported using a detection unit;
outputting a stop signal for stopping the transporting of the substrate to the transport unit based on detection of the first detection target using the detection unit;
detecting second detection target, which is provided on the substrate which has stopped and is provided to be separated by a predetermined distance from the first detection target on the substrate at least in the transportation direction, using a detection unit; and
mounting the component on the substrate with the second detection target which has been detected as a reference position.
